(19) United States
(12) Patent Application Publication
(10) Pub. No.: US 2025/0227903 A1
(43) Pub. Date: Jul. 10, 2025

(54) ELECTROMAGNETIC WAVE ABSORBER, ELECTROMAGNETIC WAVE SHIELDING MEMBER, SHIELDING MATERIAL, ELECTROMAGNETIC WAVE ABSORBING SHEET, SENSOR, DEVICE FOR RECEIVING AND/OR TRANSMITTING, AND DEVICE FOR RECEIVING LIGHT AND/OR EMITTING LIGHT

(71) Applicant: Sony Group Corporation, Tokyo (JP)

(72) Inventors: Eri IGARASHI, Tokyo (JP); Takuo TANAKA, Tokyo (JP)

(21) Appl. No.: 18/847,084

(22) PCT Filed: Mar. 14, 2022
(86) PCT No.: PCT/JP2022/011221

§ 371 Date: Sep. 13, 2024

(51) Int. Cl. H05K 9/00

(52) U.S. Cl. CPC H05K 9/00

(57) ABSTRACT

Provided is an electromagnetic wave absorber that can be downsized and have a wide response bandwidth while suppressing an increase in manufacturing cost.

The electromagnetic wave absorber according to the present technology includes a spiral body having a non-constant spiral diameter.

### TECHNICAL FIELD

The present technology relates to an electromagnetic wave absorber, an electromagnetic wave shielding member, a shielding material, an electromagnetic wave absorbing sheet, a sensor, a device that performs reception and/or transmission, and a device that performs light reception and/or light emission.

### BACKGROUND ART

Conventionally, a radio wave shielding or absorber having a laminated structure in which a plurality of layers including a metamaterial layer is laminated has been known (see, for example, Patent Document 1). This radio wave shielding or absorber can be downsized and can have a wide response bandwidth.

### CITATION LIST

### Patent Document

Patent Document 1: Japanese Patent Application Laid-Open No. 2012-089785

### SUMMARY OF THE INVENTION

### Problems to be Solved by the Invention

However, in the conventional radio wave shielding or absorber, there is room for improvement in suppressing an increase in manufacturing cost.

Therefore, a main object of the present technology is to provide an electromagnetic wave absorber that can be downsized and have a wider response bandwidth while suppressing an increase in manufacturing cost.

### Solutions to Problems

The present technology provides an electromagnetic wave absorber including a spiral body having a non-constant spiral diameter.

The spiral body may be a volute spiral body.

The electromagnetic wave absorber may have a frictional bandwidth of 30% or more and 163% or less and an absorption rate of 60% or more and 100% or less with respect to an electromagnetic wave having a frequency of 1 GHz or more.

The electromagnetic wave absorber may have the absorption rate of 70% or more.

The electromagnetic wave absorber may have the absorption rate of 80% or more.

A ratio of a spiral pitch of the volute spiral body to a wavelength of an electromagnetic wave having a frequency of 1 GHz or more may be 0.023 or more and 0.073 or less, a ratio of a radius of a minimum diameter portion of the volute spiral body to the wavelength may be 0.034 or more and 0.057 or less, a ratio of a radius of a maximum diameter portion of the volute spiral body to the radius of the minimum diameter portion may be 1.0 or more and 14 or less, and a number of turns of the volute spiral body may be one or more and ten or less.

The ratio of the spiral pitch to the wavelength may be 0.033 or more and 0.070 or less, and the ratio of the radius of the minimum diameter portion to the wavelength may be 0.037 or more and 0.054 or less.

The ratio of the spiral pitch to the wavelength may be 0.040 or more and 0.066 or less, and the ratio of the radius of the minimum diameter portion to the wavelength may be 0.039 or more and 0.053 or less.

The volute spiral body may further include a plate-shaped body disposed on the maximum diameter portion side and/or the minimum diameter portion side of the volute spiral body.

The plate-shaped body may include a semiconductor, a magnetic body, a supermagnetic body, a metal, or a dielectric.

A ratio of a distance between one of the maximum diameter portion and the minimum diameter portion closer to the plate-shaped body and the plate-shaped body to a wavelength of an electromagnetic wave having a frequency of 1 GHz or more may be 0.20 or more and 0.35 or less.

The spiral pitch of the spiral body may not be constant.

In the spiral body, a difference in a spiral radius between the spiral pitches may not be constant.

The spiral body may include any one material selected from a metal, a dielectric, a magnetic body, a semiconductor, and a superconductor.

A plurality of the spiral bodies may be arranged in an array.

The present technology also provides an electromagnetic wave shielding member including the electromagnetic wave absorber.

The present technology also provides a shielding material including the electromagnetic wave absorber.

The present technology also provides an electromagnetic wave absorbing sheet including the electromagnetic wave absorber.

The present technology also provides a sensor including the electromagnetic wave absorber.

The present technology also provides a device that performs reception and/or transmission using the electromagnetic wave absorber.

The present technology also provides a device that performs light reception and/or light emission using the electromagnetic wave absorber.

### BRIEF DESCRIPTION OF DRAWINGS

FIG. 1A is a side perspective view of an electromagnetic wave absorber according to an embodiment of the present technology. FIG. 1B is a plan view of the electromagnetic wave absorber according to the embodiment.

FIG. 2 is a perspective view of the electromagnetic wave absorber according to an embodiment of the present technology.

FIGS. 3A and 3B are diagrams illustrating a principle of electromagnetic wave absorption by the electromagnetic wave absorber according to the embodiment of the present technology.

FIGS. 4A and 4B are diagrams (part 1) illustrating absorption characteristics of the electromagnetic wave absorber according to the embodiment of the present technology.

FIGS. 5A and 5B are diagrams (part 2) illustrating absorption characteristics of the electromagnetic wave absorber according to an embodiment of the present technology.

FIG. 6 is a view illustrating a two-dimensional array structure in which a plurality of volute spiral bodies is arranged in an array on a substrate according to the embodiment.

FIG. 7 is a graph illustrating radio wave absorption characteristics of a two-dimensional array structure according to the embodiment.

FIGS. 8A to 8C are perspective views of an electromagnetic wave absorber according to Comparative examples 1 to 3.

FIG. 9 is a side view of an electromagnetic wave absorber according to Modification 1 of the embodiment of the present technology.

FIG. 10 is a side view of an electromagnetic wave absorber according to Modification 2 of the embodiment of the present technology.

FIG. 11 is a side view of an electromagnetic wave absorber according to Modification 3 of the embodiment of the present technology.

FIG. 12 is a side view of an electromagnetic wave absorber according to Modification 4 of the embodiment of the present technology.

FIG. 13 is a side view of an electromagnetic wave absorber according to Modification 5 of the embodiment of the present technology.

FIG. 14 is a side view of an electromagnetic wave absorber according to Modification 6 of the embodiment of the present technology.

FIG. 15 is a side view of an electromagnetic wave absorber according to Modification 7 of the embodiment of the present technology.

FIG. 16 is a side view of an electromagnetic wave absorber according to Modification 8 of the embodiment of the present technology.

FIG. 17 is a side view of an electromagnetic wave absorber according to Modification 9 of the embodiment of the present technology.

FIG. 18 is a side view of an electromagnetic wave absorber according to a Modification 10 of the embodiment of the present technology.

### MODE FOR CARRYING OUT THE INVENTION

Hereinafter, preferred embodiments of the present technology will be described in detail with reference to the accompanying drawings. Note that, in the present specification and the drawings, components having substantially the same functional configurations are denoted by the same reference signs, and redundant descriptions are omitted. The embodiments to be described below provide representative embodiments of the present technology, and the scope of the present technology is not to be narrowly interpreted according to those embodiments. In the present specification, even in a case where it is described that the electromagnetic wave absorber, the electromagnetic wave shielding member, the shielding material, the electromagnetic wave absorbing sheet, the sensor, the device for receiving and/or transmitting, and the device for receiving and/or emitting light according to the present technology exhibit a plurality of effects, the electromagnetic wave absorber, the electromagnetic wave shielding member, the shielding material, the electromagnetic wave absorbing sheet, the sensor, the device for receiving and/or transmitting, and the device for receiving and/or emitting light according to the present technology are only required to exhibit at least one effect. The effects described in the present specification are merely examples and are not limited, and other effects may be exerted.

Furthermore, the description will be given in the following order.
0. Introduction
1. Electromagnetic wave absorber according to one embodiment of present technology
2. Electromagnetic wave absorber according to Modifications 1 to 10 of the embodiment of the present technology
3. Other modifications of the present technology
4. Application of electromagnetic wave absorber according to present technology

### <0. Introduction>

Conventionally, a magnetic material such as ferrite has been widely used as a radio wave absorbing material, but due to a limit of a spin velocity of electrons, which is an origin of the radio wave absorbing function, it is difficult to cope with a high frequency band used in future next-generation communication, particularly a high frequency of 1 GHz or more.

As an alternative to conventional radio wave absorbers, metamaterial absorbers capable of freely controlling a corresponding frequency by a structural design have been proposed, but metamaterial exhibits a strong response only to a specific frequency since resonance of a wave is used as an operation principle, and its response bandwidth is narrow, which is a problem. As a solution to increase the response bandwidth of the metamaterial absorber, a method of using a plurality of metamaterials having different sizes in combination and a method of incorporating a lumped constant element have been proposed, but there is a trade-off with an increase in element area and an increase in manufacturing cost. In addition, an example in which a metamaterial having a spiral shape exhibits a response in a wide band has been reported in a light region, but it has been found that the frequency that can be supported by the metamaterial is limited.

Therefore, as a result of intensive studies, the present inventor has devised the electromagnetic wave absorber according to the present technology as an electromagnetic wave absorber that can be downsized and can have a wider response bandwidth while suppressing an increase in manufacturing cost. The present inventor has further studied and developed an electromagnetic wave absorber according to an embodiment of the present technology as an electromagnetic wave absorber having a high electromagnetic wave absorbing function in a response band.

### <1. Electromagnetic Wave Absorber According to One Embodiment of Present Technology>

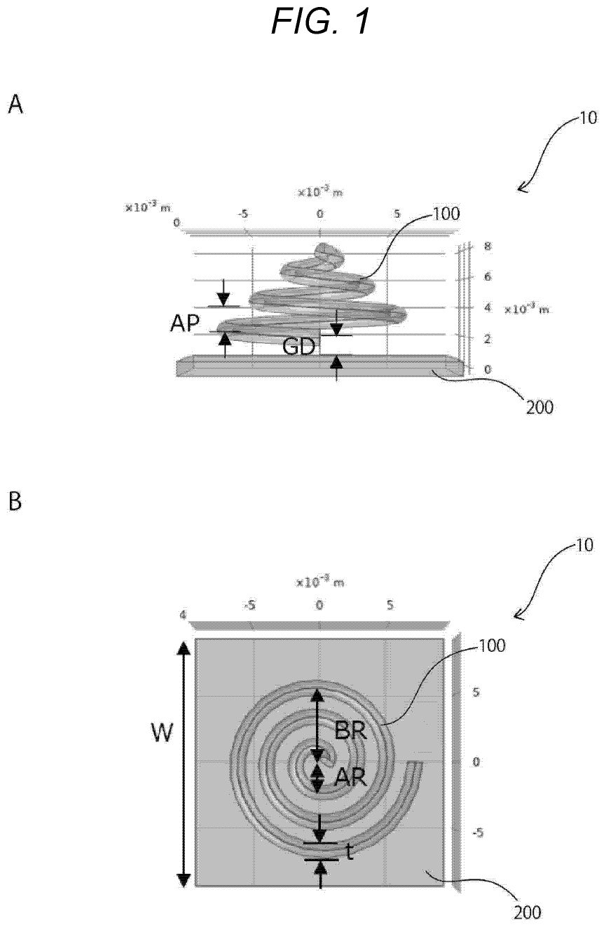

Hereinafter, an electromagnetic wave absorber 10 according to an embodiment of the present technology will be described with reference to the drawings. FIG. 1A is a side perspective view of an electromagnetic wave absorber 10 according to an embodiment. FIG. 1B is a plan view of the electromagnetic wave absorber 10 according to the embodiment.

### (Configuration of Electromagnetic Wave Absorber)

The electromagnetic wave absorber 10 is a metamaterial having a function of absorbing an electromagnetic wave. Specifically, the electromagnetic wave absorber 10 is an artificial minute structure smaller than a wavelength of an electromagnetic wave to be absorbed (for example, an electromagnetic wave (for example, a radio wave) having a frequency of 1 GHz or more).

As illustrated in FIGS. 1A and 1B, the electromagnetic wave absorber 10 includes a volute spiral body 100 (spiral body having a volute shape) which is a spiral body having a non-constant spiral diameter. As an example, the electromagnetic wave absorber 10 further includes a plate-shaped body 200 (for example, a substrate) disposed on a maximum diameter portion side of the volute spiral body 100. Note that the electromagnetic wave absorber 10 may include a plate-shaped body 200 (for example, a substrate) on a minimum diameter portion side instead of or in addition to the maximum diameter portion side of the volute spiral body 100. Here, in the electromagnetic wave absorber 10, a single volute spiral body 100 is arranged on the plate-shaped body 200 to form a unit structure, but a plurality of volute spiral bodies 100 may be arranged on the plate-shaped body 200 in an array to form a unit structure.

The volute spiral body 100 is, for example, a conical volute spiral body. As an example, the volute spiral body 100 includes any one material selected from a metal, a dielectric, a magnetic body, a semiconductor, and a superconductor, or a combination of at least two of these materials. The plate-shaped body 200 includes, for example, a semiconductor, a magnetic body, a supermagnetic body, a metal, or a dielectric. Here, the plate-shaped body 200 has a square shape in plan view, but may have another shape.

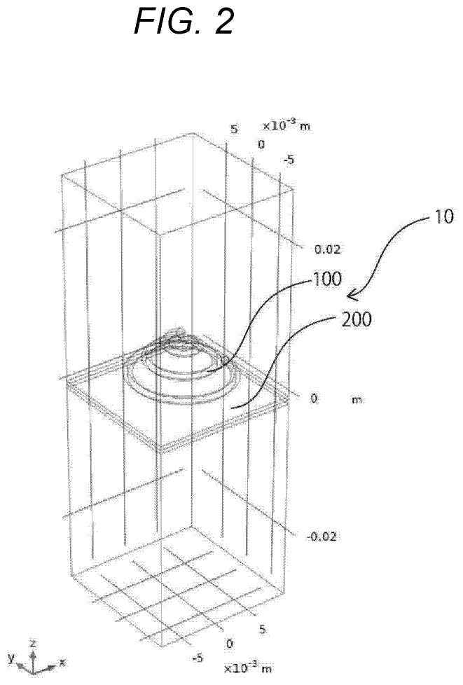

As an example, the volute spiral body 100 can be a scale (size) illustrated in FIGS. 1A, 1B, and 2. In FIG. 1A, AP represents a spiral pitch, and GD represents a distance between a maximum diameter portion of the volute spiral body 100 and the plate-shaped body 200. In FIG. 1B, AR represents a radius of the minimum diameter portion of the volute spiral body 100, BR represents a radius of the maximum diameter portion of the volute spiral body 100, t represents a wire diameter of the volute spiral body 100, and W represents a length of one side of the plate-shaped body 200. The number of turns of the volute spiral body 100 is not particularly limited, but is preferably one or more and ten or less (three turns in the example of FIGS. 1A and 1B).

### (Principle of Electromagnetic Wave Absorption by Electromagnetic Wave Absorber)

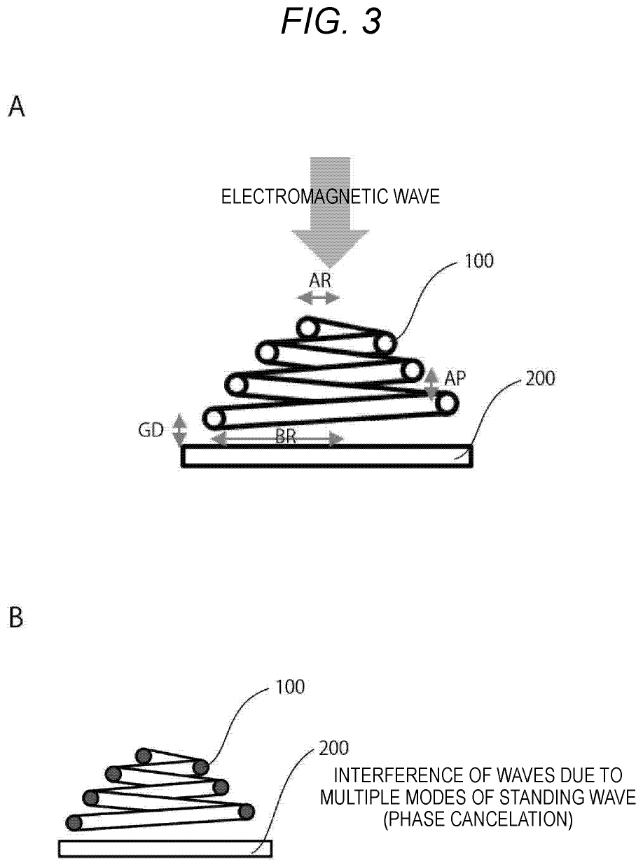

The electromagnetic wave absorber 10 can set parameters (for example, a spiral pitch AP of the volute spiral body 100, a radius AR of the minimum diameter portion, a radius BR of the maximum diameter portion, a distance GD between the maximum diameter portion and the plate-shaped body 200, and the like) illustrated in FIG. 3A to an appropriate value to interfere a plurality of modes of a standing wave of an incident electromagnetic wave so as to cancel the phase (see FIG. 3B).

### (Performance of Electromagnetic Wave Absorber)

Because of the provision of the volute spiral body 100, the electromagnetic wave absorber 10 is wide in the response bandwidth with respect to the electromagnetic wave to be absorbed, and can have a relatively high electromagnetic wave absorption function within the response bandwidth. This is an extremely important characteristic in putting the metamaterial as the electromagnetic wave absorber 10 into practical use, and is a new finding found by the present inventor. Specifically, the electromagnetic wave absorber 10 preferably has a frictional bandwidth of 30% or more and 163% or less and an absorption rate of 60% or more and 100% or less in a response band with respect to an electromagnetic wave having a frequency of 1 GHz or more. In this case, the absorption rate is more preferably 70% or more, and still more preferably 80% or more. Here, the bandwidth refers to an inter-band distance between a lower end frequency and an upper end frequency of a band in which an absorption rate is uniformly 60% or more, and the frictional bandwidth refers to a value obtained by dividing the bandwidth by a peak frequency which is a center frequency.

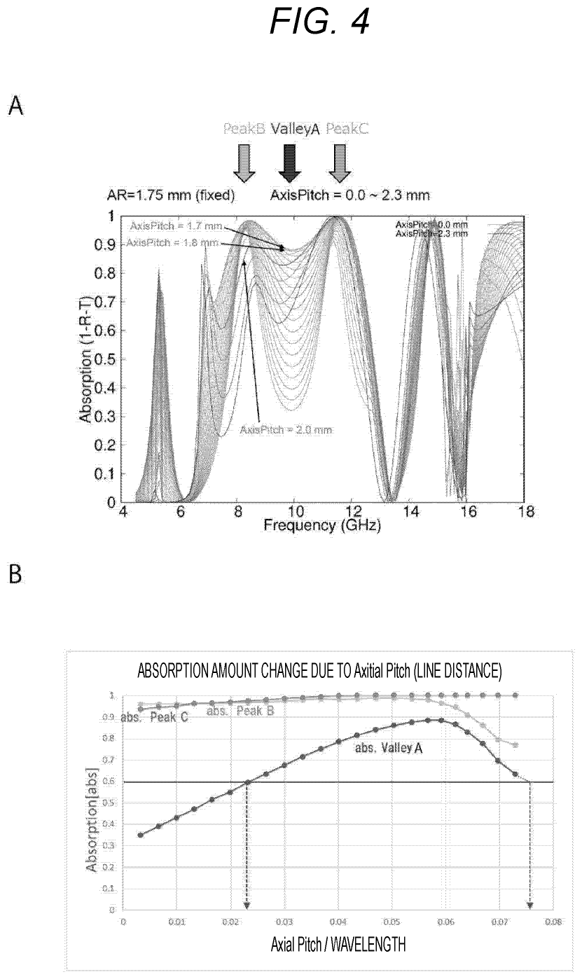

FIG. 4A is a diagram showing a relationship between the frequency (horizontal axis) of the electromagnetic wave and the absorption rate (vertical axis) of the electromagnetic wave by the electromagnetic wave absorber 10. FIG. 4A is a graph illustrating a relationship between the frequency and the absorption rate when the radius AR of the minimum diameter portion of the volute spiral body 100 is set to 1.75 mm, the ratio of the radius BR of the maximum diameter portion to the radius AR of the minimum diameter portion is set to 1.0 or more and 14 or less, the number of turns of the volute spiral body 100 is set to 1 or more and 10 or less, the ratio of the distance GD between the maximum diameter portion and the plate-shaped body 200 to the wavelength of the electromagnetic wave having the frequency of 1 GHz or more is set to 0.20 or more and 0.35 or less, and the spiral pitch AP is changed by 0 to 2.3 mm. Each graph in FIG. 4A has Valley A at 9 to 10 GHZ and Peaks B and C at 8 to 9 GHz and 11 to 12 GHz, respectively.

FIG. 4B is a graph showing a relationship between the spiral pitch AP (axial pitch)/wavelength (horizontal axis) of the electromagnetic wave and the absorption rate (vertical axis) of the electromagnetic wave by the electromagnetic wave absorber 10 for Peaks B, C, and Valley A. As can be seen from FIG. 4B, in the graphs of Peak B and Peak C, the absorption rate is 90% or more in an entire region of the horizontal axis. As can be seen from FIG. 4B, in the graph of Valley A, the absorption rate is 60% or more when the value on the horizontal axis is 0.023 or more and 0.073 or less, the absorption rate is 70% or more when the value on the horizontal axis is 0.033 or more and 0.070 or less, and the absorption rate is 80% or more when the value on the horizontal axis is 0.040 or more and 0.066 or less.

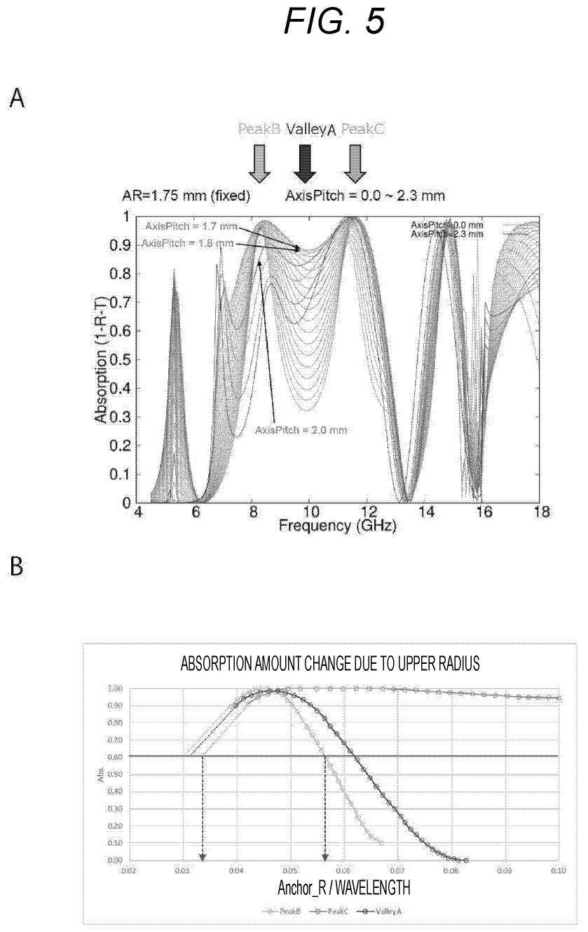

FIG. 5A is a diagram showing a relationship between the frequency (horizontal axis) of the electromagnetic wave and the absorption rate (vertical axis) of the electromagnetic wave by the electromagnetic wave absorber 10. FIG. 5A is a graph illustrating the relationship between the frequency and the absorption rate when the radius AR of the minimum diameter portion of the volute spiral body 100 is set to 1.75 mm, the ratio of the radius BR of the maximum diameter portion to the radius AR of the minimum diameter portion is set to 1.0 or more and 14 or less, the number of turns of the volute spiral body 100 is set to 1 or more and 10 or less, the ratio of the distance GD between the maximum diameter portion and the plate-shaped body 200 to the wavelength of the electromagnetic wave having the frequency of 1 GHz or more is set to 0.20 or more and 0.35 or less, and the spiral pitch AP is changed by 0 to 2.3 mm. Each graph in FIG. 5A has Valley A at 9 to 10 GHz and Peak B and Peak C at 8 to 9 GHz and 11 to 12 GHz, respectively.

FIG. 5B is a graph showing a relationship between the radius AR (Anchor_R) of the minimum diameter portion/the wavelength (horizontal axis) of the electromagnetic wave and the absorption rate (vertical axis) of the electromagnetic wave by the electromagnetic wave absorber 10 for Peaks B, C, and Valley A. As can be seen from FIG. 5B, in each graph, the absorption rate is 60% or more when a value on the horizontal axis is 0.034 or more and 0.057 or less, the absorption rate is 70% or more when the value on the horizontal axis is 0.037 or more and 0.054 or less, and the absorption rate is 80% or more when the value on the horizontal axis is 0.039 or more and 0.053 or less.

From the above consideration, in the electromagnetic wave absorber 10, the ratio of the spiral pitch AP of the volute spiral body 100 to the wavelength of the electromagnetic wave having a frequency of 1 GHZ or more is preferably 0.023 or more and 0.073 or less, the ratio of the radius AR of the minimum diameter portion of the volute spiral body 100 to the wavelength is preferably 0.034 or more and 0.057 or less, the ratio of the radius BR of the maximum diameter portion of the volute spiral body 100 to the radius AR of the minimum diameter portion is preferably 1.0 or more and 14 or less, and the number of turns of the volute spiral body 100 is preferably one or more and ten or less. As a result, the electromagnetic wave absorber 10 can obtain performance in which the frictional bandwidth is 30% or more and 163% or less and the absorption rate is 60% or more and 100% or less in the response band with respect to the electromagnetic wave having the frequency of 1 GHZ or more.

In order to more reliably obtain the above performance, it is more preferable to set the ratio of the distance between the maximum diameter portion of the volute spiral body 100 and the plate-shaped body 200 to the wavelength of the electromagnetic wave having a frequency of 1 GHz or more to 0.20 or more and 0.35 or less.

Furthermore, in the electromagnetic wave absorber 10, the ratio of the spiral pitch AP to the wavelength of the electromagnetic wave is more preferably 0.033 or more and 0.070 or less, and the ratio of the radius AR of the minimum diameter portion to the wavelength is more preferably 0.037 or more and 0.054 or less. As a result, the absorption rate can be 70% or more.

Furthermore, in the electromagnetic wave absorber 10, the ratio of the spiral pitch AP to the wavelength of the electromagnetic wave is preferably 0.040 or more and 0.066 or less, and the ratio of the radius AR of the minimum diameter portion to the wavelength is preferably 0.039 or more and 0.053 or less. As a result, the absorption rate can be 80% or more.

### (Method for Producing Electromagnetic Wave Absorber)

The electromagnetic wave absorber 10 can be manufactured, for example, by a molecular template method. Here, the molecular template method refers to a method in which a fine and complicated structure obtained from an organic substance (artificial/biopolymer, nanoparticle, liquid crystal molecule, etc.) is used as a template to form a microstructure including a material selected from, for example, any one of a metal, a dielectric, a magnetic body, a semiconductor, and a superconductor, or a combination of a plurality of these. Three methods are mainly known for the molecular template method. The first is a method of performing coating such as plating on an organic structure. The second method is a method in which a precursor such as a metal or an oxide is formed into a structure by an organic substance introduced in advance, and the structure is converted into a metal, an oxide, or the like by firing, oxidation-reduction, or the like. The third method is a method of forming a structure by etching a metal film prepared on a substrate such as a dielectric and then bending the metal pattern due to stress.

### Example

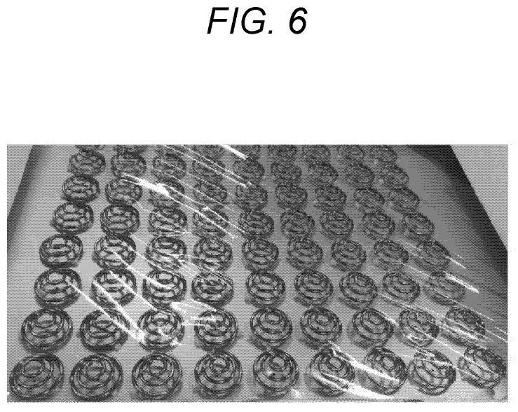

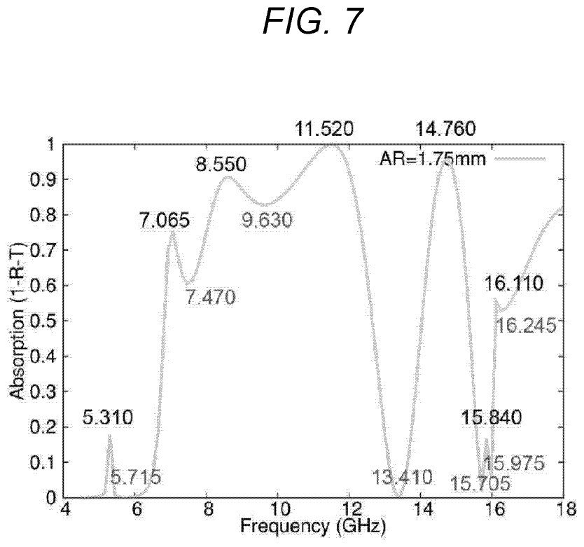

A three-turn volute spiral body with AR (upper radius)=1.75 mm, BR (lower radius)=8.15 mm, AP (spiral pitch)=2.0 mm, and t (wire diameter)=1.1 mm was disposed on a single side FR-4 (Flame Retardant Type4) substrate (glass epoxy substrate) with 450 mm×450 mm×0.2 mm and copper foil thickness of 0.037 mm. A polystyrene spacer was used to fix the volute spiral body to the substrate. A distance GD between the upper surface of the substrate and the maximum diameter portion of the volute spiral body was set to 2.0 mm, and a plurality of volute spiral bodies was arranged in a matrix at equal intervals W=18.7 mm to produce a two-dimensional array structure in which 9×9 volute spiral bodies illustrated in FIG. 6 were arranged on the substrate. Radio wave absorption characteristics at 4 to 18 GHz of the two-dimensional array structure prepared by this method were evaluated by an S-parameter method. The absorption intensity A was obtained by A=1−T−R where a transmission intensity was T and a reflection intensity was R. As shown in FIG. 7, the two-dimensional array structure produced by this method indicated the absorption intensity of 80% or more over the frictional bandwidth of 42% (8.2 to 13 GHZ).

### (Effects of Electromagnetic Wave Absorber)

The electromagnetic wave absorber 10 according to the embodiment of the present technology includes the volute spiral body 100 which is a spiral body having a non-constant spiral diameter. The volute spiral body 100 is a structure capable of reducing an element area and widening a response bandwidth without complicating a manufacturing process. According to the electromagnetic wave absorber 10, it is possible to provide an electromagnetic wave absorber that can be downsized and have a wide response bandwidth while suppressing an increase in manufacturing cost.

The electromagnetic wave absorber 10 preferably has the frictional bandwidth of 30% or more and 163% or less and the absorption rate of 60% or more and 100% or less with respect to the electromagnetic wave having the frequency of 1 GHz or more. As a result, the performance of the electromagnetic wave absorber 10 can be increased to a practical level. Furthermore, the electromagnetic wave absorber 10 can increase the absorption rate to 70% or more, and even 80% or more in the response band, and can also be applied to applications requiring higher performance.

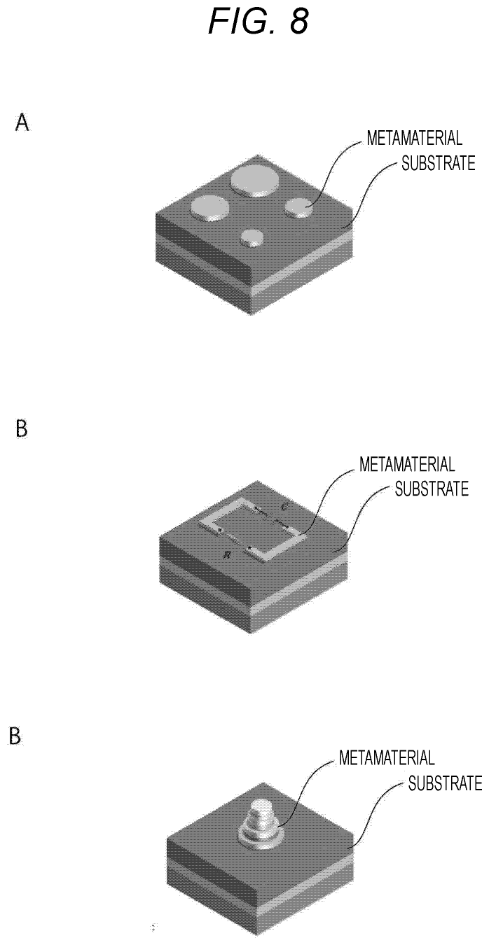

On the other hand, for example, in the electromagnetic wave absorbers of Comparative examples 1 and 3 shown in FIGS. 8A and 8C, since a plurality of metamaterials is arranged side by side on a substrate to form a unit structure, an element area is increased, leading to an increase in size.

For example, in the electromagnetic wave absorber of Comparative Example 2 shown in FIG. 8B, a plurality of layers including a metamaterial layer is laminated to form a unit structure, so that a manufacturing process becomes complicated, leading to an increase in manufacturing cost.

### <2. Electromagnetic Wave Absorber According to Modification 1 to 9 of the Embodiment of the Present Technology>

Hereinafter, Modifications 1 to 9 of the embodiment of the present technology will be described with reference to the drawings.

### (Modification 1)

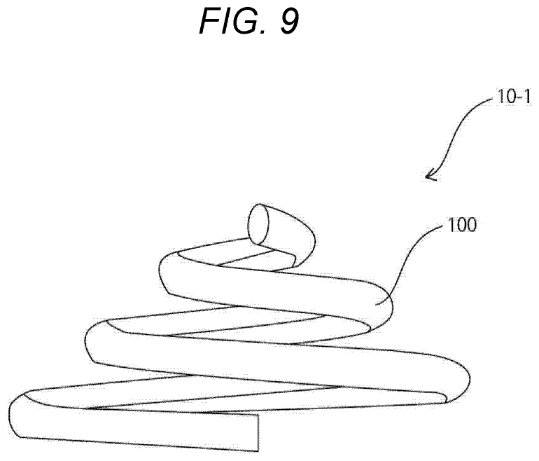

FIG. 9 is a side view of an electromagnetic wave absorber 10-1 according to Modification 1 of the embodiment of the present technology. As illustrated in FIG. 9, the electromagnetic wave absorber 10-1 has the similar configuration to that of the electromagnetic wave absorber 10 according to the embodiment except that the plate-shaped body 200 is not provided.

The electromagnetic wave absorber 10-1 can also have desired performance (performance in which a frictional bandwidth is 30% or more and 163% or less and an absorption rate is 60% or more and 100% or less in a response band with respect to an electromagnetic wave having a frequency of 1 GHz or more) by setting each parameter of the volute spiral body 100 to an appropriate value similarly to the case of the electromagnetic wave absorber 10. In this case, the absorption rate can be increased to 70% or more, and further to 80% or more.

### (Modification 2)

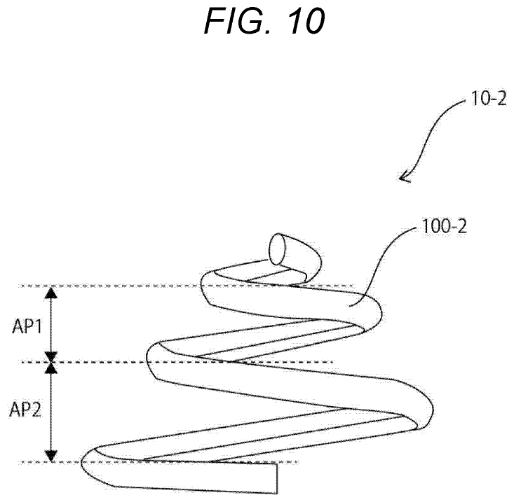

FIG. 10 is a side view of an electromagnetic wave absorber 10-2 according to Modification 2 of the embodiment of the present technology. As illustrated in FIG. 10, the electromagnetic wave absorber 10-2 has the similar configuration to that of the electromagnetic wave absorber 10-1 according to Modification 1 except that the spiral pitch of the volute spiral body 100-2 is not constant (non-uniform).

In the electromagnetic wave absorber 10-2, the spiral pitch of the volute spiral body 100-2 becomes longer from a minimum diameter portion side to a maximum diameter portion side. Specifically, in the volute spiral body 100-2, a spiral pitch AP2 on the maximum diameter portion side is longer than a spiral pitch AP1 on the minimum diameter portion side.

The electromagnetic wave absorber 10-2 can also have desired performance (performance in which a frictional bandwidth is 30% or more and 163% or less and an absorption rate is 60% or more and 100% or less in a response band with respect to an electromagnetic wave having a frequency of 1 GHz or more) by setting each parameter of the volute spiral body 100-2 to an appropriate value similarly to the case of the electromagnetic wave absorber 10. In this case, the absorption rate can be increased to 70% or more, and further to 80% or more. Furthermore, in the electromagnetic wave absorber 10-2, a specific effect (for example, response frequency control, frictional bandwidth extension, and the like) due to the non-uniform spiral pitch of the volute spiral body 100-2 can also be expected.

### (Modification 3)

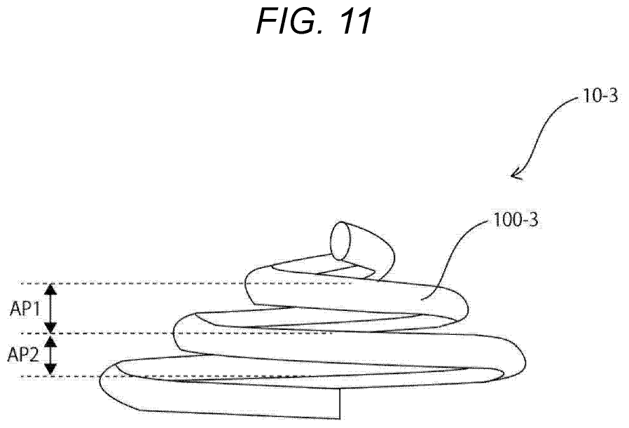

FIG. 11 is a side view of an electromagnetic wave absorber 10-3 according to Modification 3 of the embodiment of the present technology. As illustrated in FIG. 11, the electromagnetic wave absorber 10-3 has the similar configuration to that of the electromagnetic wave absorber 10-1 according to Modification 1 except that the spiral pitch of the volute spiral body 100-3 is not constant (non-uniform).

In the electromagnetic wave absorber 10-3, a spiral pitch of the volute spiral body 100-3 is shortened from a minimum diameter portion side to a maximum diameter portion side. Specifically, in the volute spiral body 100-3, a spiral pitch AP2 on the maximum diameter portion side is shorter than a spiral pitch AP1 on the minimum diameter portion side.

The electromagnetic wave absorber 10-3 can also have desired performance (performance in which a frictional bandwidth is 30% or more and 163% or less and an absorption rate is 60% or more and 100% or less in a response band with respect to an electromagnetic wave having a frequency of 1 GHz or more) by setting each parameter of the volute spiral body 100-3 to an appropriate value similarly to the case of the electromagnetic wave absorber 10. In this case, the absorption rate can be increased to 70% or more, and further to 80% or more. Furthermore, in the electromagnetic wave absorber 10-3, a specific effect (for example, response frequency control, frictional bandwidth extension, and the like) due to the non-uniform spiral pitch of the volute spiral body 100-3 can also be expected.

### (Modification 4)

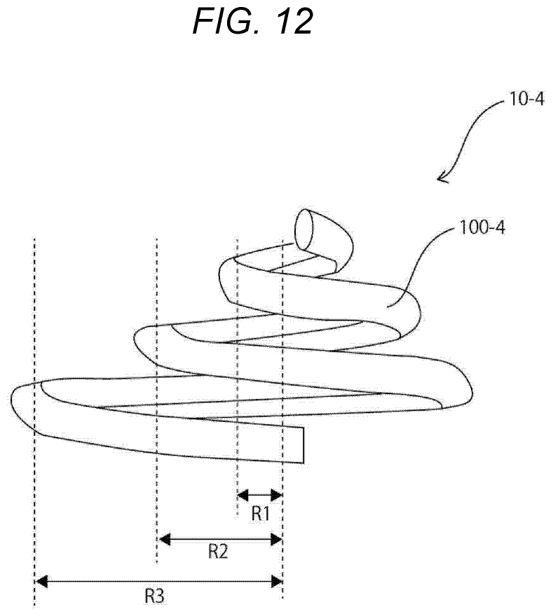

FIG. 12 is a side view of an electromagnetic wave absorber 10-4 according to Modification 4 of the embodiment of the present technology. As illustrated in FIG. 12, an electromagnetic wave absorber 10-4 has the similar configuration to that of the electromagnetic wave absorber 10-1 according to Modification 1 except that a difference in spiral radius between spiral pitches of the volute spiral body 100-4 is not constant.

In the electromagnetic wave absorber 10-4, the difference in spiral radius between the spiral pitches of the volute spiral body 100-4 increases from a minimum diameter portion side to a maximum diameter portion side. Specifically, in the volute spiral body 100-4, a difference R3−R2 between a spiral radius R3 of a maximum diameter portion and a spiral radius R2 of an intermediate diameter portion is larger than a difference R2−R1 between the spiral radius R2 of the intermediate diameter portion and the spiral radius R1 of the minimum diameter portion.

The electromagnetic wave absorber 10-4 can also have desired performance (performance in which a frictional bandwidth is 30% or more and 163% or less and an absorption rate is 60% or more and 100% or less in a response band with respect to an electromagnetic wave having a frequency of 1 GHz or more) by setting each parameter of the volute spiral body 100-4 to an appropriate value similarly to the case of the electromagnetic wave absorber 10. In this case, the absorption rate can be increased to 70% or more, and further to 80% or more. Furthermore, in the electromagnetic wave absorber 10-4, a specific effect (for example, response frequency control, frictional bandwidth extension, and the like) due to the non-uniform difference in spiral radius between the spiral pitches of the volute spiral body 100-4 can also be expected.

### (Modification 5)

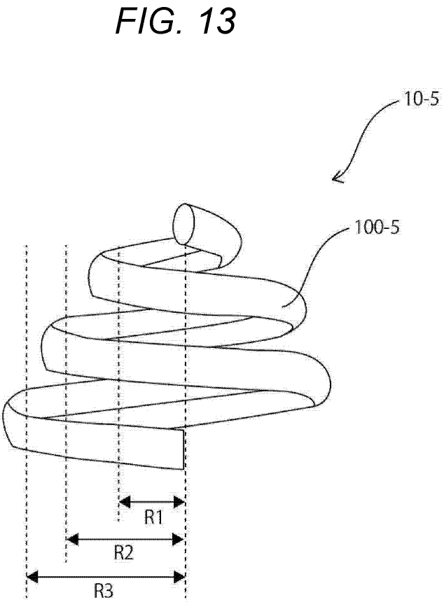

FIG. 13 is a side view of an electromagnetic wave absorber 10-5 according to Modification 5 of the embodiment of the present technology. As illustrated in FIG. 13, the electromagnetic wave absorber 10-5 has the similar configuration to that of the electromagnetic wave absorber 10-1 according to Modification 1 except that a difference in spiral radius between spiral pitches of the volute spiral body 100-5 is not constant.

In the electromagnetic wave absorber 10-5, a difference in spiral radius between the spiral pitches of the volute spiral body 100-5 decreases from a minimum diameter portion side to a maximum diameter portion side. Specifically, in the volute spiral body 100-5, a difference R3−R2 between a spiral radius R3 of the maximum diameter portion and a spiral radius R2 of an intermediate diameter portion is smaller than a difference R2−R1 between the spiral radius R2 of the intermediate diameter portion and a spiral radius R1 of the minimum diameter portion.

The electromagnetic wave absorber 10-5 can also have desired performance (performance in which a frictional bandwidth is 30% or more and 163% or less and an absorption rate is 60% or more and 100% or less in a response band with respect to an electromagnetic wave having a frequency of 1 GHz or more) by setting each parameter of the volute spiral body 100-5 to an appropriate value similarly to the case of the electromagnetic wave absorber 10. In this case, the absorption rate can be increased to 70% or more, and further to 80% or more. Furthermore, in the electromagnetic wave absorber 10-5, a specific effect (for example, response frequency control, frictional bandwidth extension, and the like) due to the non-uniform difference in spiral radius between the spiral pitches of the volute spiral body 100-5 can also be expected.

### (Modification 6)

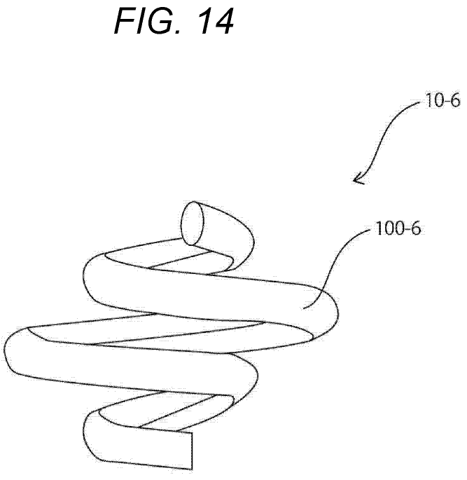

FIG. 14 is a side view of an electromagnetic wave absorber 10-6 according to Modification 6 of the embodiment of the present technology. As shown in FIG. 14, the electromagnetic wave absorber 10-6 has the similar configuration to that of the electromagnetic wave absorber 10-1 according to Modification 1 except that the volute spiral body 100-6 has an outer shape (substantially vertically symmetrical outer shape) in which bottom surfaces of two cones having the same shape and the same size are bonded to each other.

In the electromagnetic wave absorber 10-6, for example, the number of turns is three in the volute spiral body 100-6, but the number of turns may be one, two, or four or more.

The electromagnetic wave absorber 10-6 can also have desired performance (performance in which a frictional bandwidth is 30% or more and 163% or less and an absorption rate is 60% or more and 100% or less in a response band with respect to an electromagnetic wave having a frequency of 1 GHz or more) by setting each parameter of the volute spiral body 100-6 to an appropriate value similarly to the case of the electromagnetic wave absorber 10. In this case, the absorption rate can be increased to 70% or more, and further to 80% or more. Furthermore, in the electromagnetic wave absorber 10-6, a specific effect (for example, response frequency control, frictional bandwidth extension, absorption rate improvement, and the like) due to the volute spiral body 100-6 having a substantially vertically symmetrical shape can also be expected.

### (Modification 7)

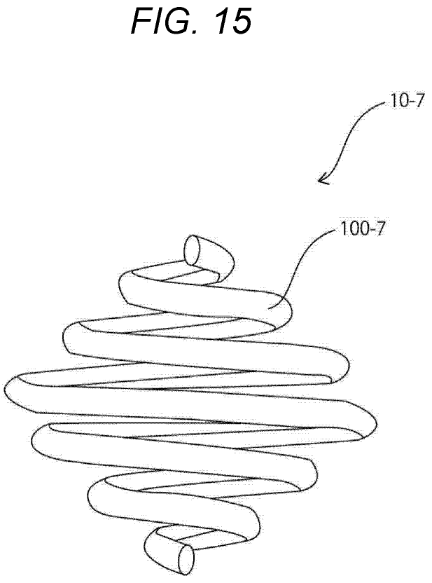

FIG. 15 is a side view of an electromagnetic wave absorber 10-7 according to Modification 7 of the embodiment of the present technology. As illustrated in FIG. 15, the electromagnetic wave absorber 10-7 has the similar configuration to that of the electromagnetic wave absorber 10-1 according to Modification 1 except that the volute spiral body 100-7 has a configuration (substantially vertically symmetrical configuration) in which the two volute spiral bodies 100 of the electromagnetic wave absorber 10-1 according to Modification 1 are joined at a maximum diameter portion.

The electromagnetic wave absorber 10-7 can also have desired performance (performance in which a frictional bandwidth is 30% or more and 163% or less and an absorption rate is 60% or more and 100% or less in a response band with respect to an electromagnetic wave having a frequency of 1 GHz or more) by setting each parameter of the volute spiral body 100-7 to an appropriate value similarly to the case of the electromagnetic wave absorber 10. In this case, the absorption rate can be increased to 70% or more, and further to 80% or more. Furthermore, in the electromagnetic wave absorber 10-7, a specific effect (for example, response frequency control, frictional bandwidth extension, absorption rate improvement, and the like) due to the volute spiral body 100-7 having a substantially vertically symmetrical shape can also be expected.

### (Modification 8)

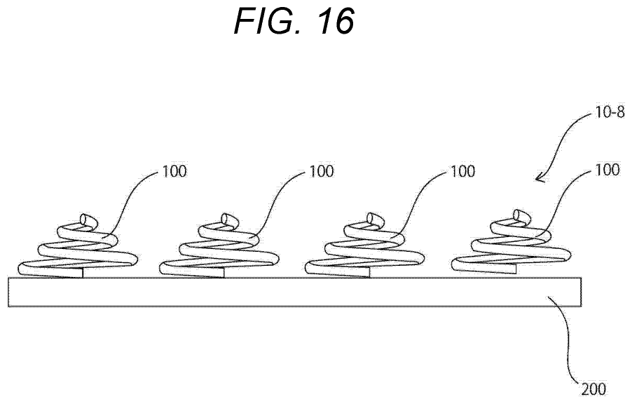

FIG. 16 is a side view of an electromagnetic wave absorber 10-8 according to Modification 8 of the embodiment of the present technology. As illustrated in FIG. 16, an electromagnetic wave absorber 10-8 has the similar configuration to that of the electromagnetic wave absorber 10 according to the embodiment except that a plurality of volute spiral bodies 100 are arranged in an array (for example, a one-dimensional array or a two-dimensional array) on a plate-shaped body 200.

The electromagnetic wave absorber 10-8 is suitable for applications requiring a larger electromagnetic wave absorbing surface. Note that, also in this case, since each volute spiral body 100 of the electromagnetic wave absorber 10-8 is small, it is possible to arrange the volute spiral bodies on the plate-shaped body 200 at high density.

### (Modification 9)

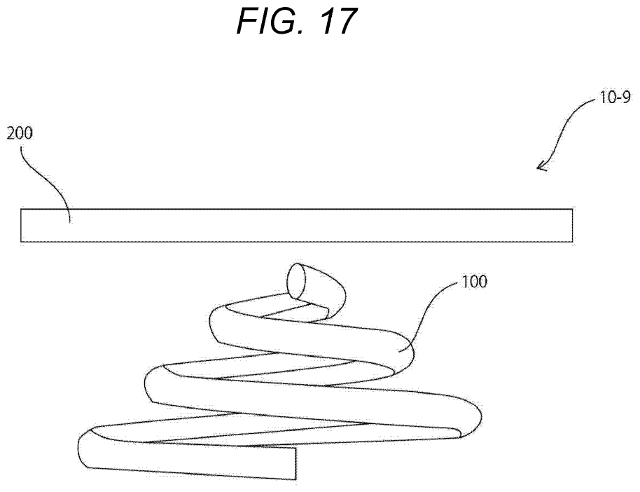

FIG. 17 is a side view of an electromagnetic wave absorber 10-9 according to Modification 9 of the embodiment of the present technology. As illustrated in FIG. 17, the electromagnetic wave absorber 10-9 has the similar configuration to that of the electromagnetic wave absorber 10 according to the embodiment except that a plate-shaped body 200 is disposed on a minimum diameter portion side of the volute spiral body 100.

The electromagnetic wave absorber 10-9 can also have desired performance (performance in which a frictional bandwidth is 30% or more and 163% or less and an absorption rate is 60% or more and 100% or less in a response band with respect to an electromagnetic wave having a frequency of 1 GHz or more) by setting each parameter of the volute spiral body 100 and a distance between a minimum diameter portion of the volute spiral body 100 and a plate-shaped body 200 to appropriate values similarly to the case of the electromagnetic wave absorber 10. In this case, the absorption rate can be increased to 70% or more, and further to 80% or more.

### (Modification 10)

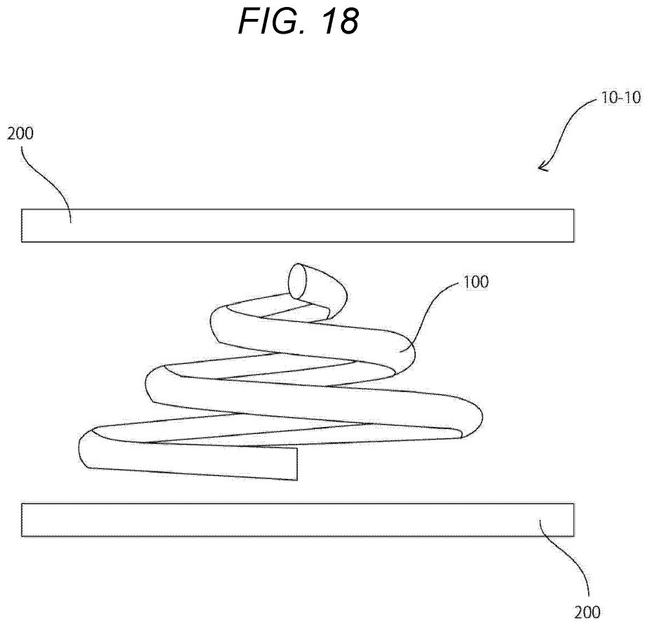

FIG. 18 is a side view of an electromagnetic wave absorber 10-10 according to Modification 10 of the embodiment of the present technology. As illustrated in FIG. 18, the electromagnetic wave absorber 10-10 has the similar configuration to that of the electromagnetic wave absorber 10 according to the embodiment except that plate-shaped bodies 200 are disposed on a minimum diameter portion side and a maximum diameter portion side of a volute spiral body 100.

The electromagnetic wave absorber 10-9 can also have desired performance (performance in which a frictional bandwidth is 30% or more and 163% or less and an absorption rate is 60% or more and 100% or less in a response band with respect to an electromagnetic wave having a frequency of 1 GHz or more) by setting each parameter of the volute spiral body 100, the distance between the minimum diameter portion of the volute spiral body 100 and the plate-shaped body 200 on the minimum diameter portion side, and the distance between the maximum diameter portion of the volute spiral body 100 and the plate-shaped body 200 on the maximum diameter portion side to appropriate values similarly to the case of the electromagnetic wave absorber 10. In this case, the absorption rate can be increased to 70% or more, and further to 80% or more.

### <3. Other Modifications of the Present Technology>

The electromagnetic wave absorber according to the present technology is not limited to the above-described embodiment and each modification, and can be appropriately changed.

The spiral body of the electromagnetic wave absorber according to the present technology is not limited to the volute spiral body, and may be any spiral body as long as the spiral diameter is not constant. For example, the spiral body may have a structure in which a plurality of different spiral radii is periodically repeated in the axial direction. For example, a spiral body having an outer shape having a narrowing portion may be used. For example, the spiral body may have different axes between at least two spiral pitches.

Some of the configurations of the electromagnetic wave absorbers according to the above embodiment and modifications may be combined within a range in which they do not contradict each other.

### <4. Application of Electromagnetic Wave Absorber According to the Present Technology>

The electromagnetic wave absorber (for example, the electromagnetic wave absorber 10 according to the embodiment, and the electromagnetic wave absorbers 10-1 to 10-10 according to Modifications 1 to 10) according to the present technology can be applied to, for example, an electromagnetic wave shielding member, a shielding material, an electromagnetic wave absorbing sheet, a sensor, a device that performs reception and/or transmission using the electromagnetic wave absorber, a device that performs light reception and/or light emission using the electromagnetic wave absorber, and the like.

Note that the present technology can have the following configurations.

(1) An electromagnetic wave absorber including a spiral body having a spiral diameter that is not constant.

(2) The electromagnetic wave absorber according to (1), in which the spiral body is a volute spiral body.

(3) The electromagnetic wave absorber according to (1) or (2), in which a frictional bandwidth is 30% or more and 163% or less and an absorption rate is 60% or more and 100% or less with respect to an electromagnetic wave having a frequency of 1 GHz or more.

(4) The electromagnetic wave absorber according to (3), in which the absorption rate is 70% or more.

(5) The electromagnetic wave absorber according to (3) or (4), in which the absorption rate is 80% or more.

(6) The electromagnetic wave absorber according to any one of (2) to (5), in which a ratio of a spiral pitch of the volute spiral body to a wavelength of an electromagnetic wave having a frequency of 1 GHz or more is 0.023 or more and 0.073 or less, a ratio of a radius of a minimum diameter portion of the volute spiral body to the wavelength is 0.034 or more and 0.057 or less, a ratio of a radius of a maximum diameter portion of the volute spiral body to the radius of the minimum diameter portion is 1.0 or more and 14 or less, and a number of turns of the volute spiral body is one or more and ten or less.

(7) The electromagnetic wave absorber according to (6), in which a ratio of the spiral pitch to the wavelength is 0.033 or more and 0.070 or less, and a ratio of the radius of the minimum diameter portion to the wavelength is 0.037 or more and 0.054 or less.

(8) The electromagnetic wave absorber according to (6) or (7), in which a ratio of the spiral pitch to the wavelength is 0.040 or more and 0.066 or less, and a ratio of the radius of the minimum diameter portion to the wavelength is 0.039 or more and 0.053 or less.

(9) The electromagnetic wave absorber according to any one of (2) to (8), further including a plate-shaped body disposed on a maximum diameter portion side and/or a minimum diameter portion side of the volute spiral body.

(10) The electromagnetic wave absorber according to (9), in which the plate-shaped body includes a semiconductor, a magnetic body, a supermagnetic body, a metal, or a dielectric.

(11) The electromagnetic wave absorber according to (9) or (10), in which a ratio of a distance between one of the maximum diameter portion and the minimum diameter portion which is closer to the plate-shaped body and the plate-shaped body to a wavelength of an electromagnetic wave having a frequency of 1 GHz or more is 0.20 or more and 0.35 or less.

(12) The electromagnetic wave absorber according to any one of (1) to (11), in which a spiral pitch of the spiral body is not constant.

(13) The electromagnetic wave absorber according to any one of (1) to (12), in which the spiral body has a non-constant difference in spiral radius between spiral pitches.

(14) The electromagnetic wave absorber according to any one of (1) to (13), in which the spiral body includes any one material selected from a metal, a dielectric, a magnetic body, a semiconductor, and a superconductor, or a material obtained by combining at least two of these materials.

(15) The electromagnetic wave absorber according to any one of (1) to (14), in which a plurality of the spiral bodies is arranged in an array.

(16) An electromagnetic wave shielding member including the electromagnetic wave absorber according to any one of (1) to (15).

(17) A shielding material including the electromagnetic wave absorber according to any one of (1) to (15).

(18) An electromagnetic wave absorbing sheet including the electromagnetic wave absorber according to any one of (1) to (15).

(19) A sensor including the electromagnetic wave absorber according to any one of (1) to (15).

(20) A device that performs reception and/or transmission using the electromagnetic wave absorber according to any one of (1) to (15).

(21) A device that performs light reception and/or light emission using the electromagnetic wave absorber according to any one of (1) to (15).

### REFERENCE SIGNS LIST

10, 10-1 to 10-10 Electromagnetic wave absorber
100, 100-2 to 100-7 volute spiral body
200 Plate-shaped body
AP Spiral pitch
AR Radius of minimum diameter portion
BR Radius of maximum diameter portion
GD Distance between maximum diameter portion and plate-shaped body

1. An electromagnetic wave absorber comprising a spiral body having a spiral diameter that is not constant.

2. The electromagnetic wave absorber according to claim 1, wherein the spiral body is a volute spiral body.

3. The electromagnetic wave absorber according to claim 2, wherein a frictional bandwidth is 30% or more and 163% or less and an absorption rate is 60% or more and 100% or less with respect to an electromagnetic wave having a frequency of 1 GHz or more.

4. The electromagnetic wave absorber according to claim 3, wherein the absorption rate is 70% or more.

5. The electromagnetic wave absorber according to claim 3, wherein the absorption rate is 80% or more.

6. The electromagnetic wave absorber according to claim 2, wherein
a ratio of a spiral pitch of the volute spiral body to a wavelength of an electromagnetic wave having a frequency of 1 GHz or more is 0.023 or more and 0.073 or less,
a ratio of a radius of a minimum diameter portion of the volute spiral body to the wavelength is 0.034 or more and 0.057 or less,
a ratio of a radius of a maximum diameter portion of the volute spiral body to the radius of the minimum diameter portion is 1.0 or more and 14 or less, and
a number of turns of the volute spiral body is one or more and ten or less.

7. The electromagnetic wave absorber according to claim 6, wherein a ratio of the spiral pitch to the wavelength is 0.033 or more and 0.070 or less, and
a ratio of the radius of the minimum diameter portion to the wavelength is 0.037 or more and 0.054 or less.

8. The electromagnetic wave absorber according to claim 6, wherein a ratio of the spiral pitch to the wavelength is 0.040 or more and 0.066 or less, and
a ratio of the radius of the minimum diameter portion to the wavelength is 0.039 or more and 0.053 or less.

9. The electromagnetic wave absorber according to claim 2, further comprising a plate-shaped body disposed on a maximum diameter portion side and/or a minimum diameter portion side of the volute spiral body.

10. The electromagnetic wave absorber according to claim 9, wherein the plate-shaped body includes a semiconductor, a magnetic body, a supermagnetic body, a metal, or a dielectric.

11. The electromagnetic wave absorber according to claim 9, wherein a ratio of a distance between one of the maximum diameter portion and the minimum diameter portion which is closer to the plate-shaped body and the plate-shaped body to a wavelength of an electromagnetic wave having a frequency of 1 GHz or more is 0.20 or more and 0.35 or less.

12. The electromagnetic wave absorber according to claim 1, wherein a spiral pitch of the spiral body is not constant.

13. The electromagnetic wave absorber according to claim 1, wherein the spiral body has a non-constant difference in spiral radius between spiral pitches.

14. The electromagnetic wave absorber according to claim 1, wherein the spiral body includes any one material selected from a metal, a dielectric, a magnetic body, a semiconductor, and a superconductor, or a material obtained by combining at least two of these materials.

15. The electromagnetic wave absorber according to claim 1, wherein a plurality of the spiral bodies is arranged in an array.

16. An electromagnetic wave shielding member comprising the electromagnetic wave absorber according to claim 1.

17. A shielding material comprising the electromagnetic wave absorber according to claim 1.

18. An electromagnetic wave absorbing sheet comprising the electromagnetic wave absorber according to claim 1.

19. A sensor comprising the electromagnetic wave absorber according to claim 1.

20. A device that performs reception and/or transmission using the electromagnetic wave absorber according to claim 1.

21. A device that receives light and/or emits light using the electromagnetic wave absorber according to claim 1.
